(19) United States
(12) Patent Application Publication
(10) Pub. No.: US 2015/0041200 A1
(43) Pub. Date: Feb. 12, 2015

(54) SOLDERING METHOD AND CORRESPONDING SOLDERING DEVICE

(71) Applicant: Isabellenhuette Heusler GmbH & Co. KG, Dillenburg (DE)

(72) Inventors: Ullrich Hetzler, Dillenburg-Oberscheld (DE); Ruediger Stuehn, Weitefeld (DE)

(21) Appl. No.: 14/376,322

(22) PCT Filed: Dec. 21, 2012
(86) PCT No.: PCT/EP2012/005350

§ 371 Date: Aug. 1, 2014

(30) Foreign Application Priority Data
Feb. 1, 2012 (DE) 10 2012 001 883.5

(51) Int. Cl. H05K 1/02; H05K 1/18; H05K 1/11; H05K 3/34

(52) U.S. Cl. CPC H05K 1/0212; H05K 3/3494; H05K 1/181; H05K 1/111
USPC 174/260; 29/840; 29/739

(57) ABSTRACT

The invention relates to a soldering method and a corresponding soldering device for soldering a printed circuit board (2) to an electric component (8) using a solder (6, 7), said solder (6, 7) being melted by heat and then connecting the component (8) to the printed circuit board (2). The heat required to melt the solder (6, 7) is generated by electrically energizing the component (8), thereby generating an electric heat loss in the component (8), said heat loss being transferred from the component (8) to the solder (6, 7) and melting the solder (6, 7).

The invention refers to a soldering method and a corresponding soldering device for soldering a printed circuit board to an electric component, such as a current sense resistor (shunt), using a solder.

When conventionally equipping printed circuit boards with SMD components (SMD: Surface Mounted Device), the heat required to fuse the solder is provided in an oven which is heated by a separate heat source. The disadvantage of this known soldering method is firstly that a separate heat source is required to heat the solder. A further disadvantage of this known soldering method is that the entire printed circuit board with soldering points and the components is usually heated in the oven which is unnecessary and can be harmful to heat-sensitive components.

Furthermore, so-called resistance soldering is known from the state of the art in which an electrical current flows through the actual soldering point with the solder, whereby the electrical heat loss causes the solder to melt. So far, however, resistance soldering has not yet been used to equip printed circuit boards with electrical components. This is also because separate connections would be necessary to conduct the electrical current through the soldering point.

It is known from DE 10 2009 031 227 A1 that a heating current can be applied to an electrical conductor in order to solder the conductor with a printed circuit board substrate using the resultant heat loss. However, the conductor is not an electronic component. This known soldering method is therefore not suitable for the soldering of an electronic component.

A soldering method is furthermore known from U.S. Pat. No. 4,582,975 in order to connect an integrated circuit with a printed circuit board. However, the heat required to melt the solder here is generated by a separate electrical heater in the integrated circuit. The disadvantage of this known soldering method is therefore the necessity of a corresponding modification of the integrated circuit.

The invention is therefore based on the object of creating an appropriately improved soldering method and a corresponding soldering device.

This object is solved by an inventive soldering method and by a corresponding soldering device in accordance with the independent claims.

The invention comprises the general technical teaching to generate the heat necessary to melt the solder by running an electrical current through the component to be assembled, whereby the electrical current in the component generates an electrical heat loss which passes from the component to the solder, thereby causing the solder to melt.

Unlike the resistance soldering referred to at the beginning, the electrical heat loss is not generated directly in the soldering point or the solder, but in the component to be assembled. This offers the advantage that no separate electrical connections are required for the application of electrical current to the component because the connections can be used to apply the electrical current to the component which are also used during operation of the printed circuit board layout with the electrical component.

The component is preferably a passive component such as a resistor. However, the invention is not restricted to passive components (e.g. resistors) with respect to the component to be assembled, but can basically also be realised with other types of components which generate heat when an electrical current is applied to them which can be used to melt the solder.

However, in a preferred embodiment of the invention, the component to be assembled is a resistor, which comprises a resistance element made of a resistance material (e.g. Manganin®) and two connectors made of a conducting material (e.g. copper), whereby the resistance element is connected electrically between the two connectors so that the electrical current is introduced via one of the two connectors in the resistor and flows from here through the resistance element into the other connector, from where the electrical current is then dissipated from the resistor. Such low-ohm current sense resistors are known from the state of the art and are described for example in EP 0 605 800 A1, so that full reference is made to the content of this publication in terms of the structure and functioning of the resistor described here.

In agreement with the conventional SMD soldering method, the inventive soldering method provides for the solder to be applied for example in the form of soldering paste on soldering pads (connection areas) of the printed circuit board and/or to the connectors of the resistor, whereby the solder adheres to the soldering pads. Finally, the printed circuit board is assembled with the resistor so that the solder is between the soldering pads of the printed circuit board and the connectors of the resistor. Electrical current is then applied to the resistor so that the electrical heat loss arising in the resistance element is transferred to the solder via the connectors of the resistor, thereby causing the solder to melt. It is advantageous here that the resistance material of the resistance element and also the conducting material of the connectors have a high thermal conductivity which leads to a corresponding good transfer of heat from the resistance element to the solder. A cooling phase then follows the energizing of the resistance element in which the resistor with the printed circuit board cools together with the solder so that the solder becomes rigid and connects the connectors of the resistor electrically and mechanically with the soldering pads of the printed circuit board.

If the component to be assembled is a current sense resistory, the soldering pads of the printed circuit board preferably form voltage taps in order to measure a drop in voltage across the resistance element of the resistor. The soldering pads of the printed circuit board which serve as voltage taps are preferably arranged here such that the solder is in contact with the connectors of the resistor directly at the transition between the connectors and the resistance element. This is advantageous because the voltage measured then virtually exclusively reflects the voltage drop across the resistance element without this measured value being falsified by a drop in voltage across the connectors.

In addition, an electronic measuring circuit is preferably also assembled on the printed circuit board in order to measure the voltage drop across the resistance element of the resistor. Such measuring circuits are known and described, for example, in EP 1 363 131 A1 so that so that full reference is made to the content of this publication in terms of the structure and functioning of the measuring circuit described here. It is merely to be mentioned at this point that the measuring circuit can be an ASIC (Application Specific Integrated Circuit). When assembling the electronic measuring circuit on the printed circuit board, a connection is also created between the connectors of the resistor via the corresponding soldering pads of the printed circuit board and the measuring circuit so that the measuring circuit can measure the voltage drop across the resistance element of the resistor.

In the preferred embodiment the two connectors and the resistance element of the resistor are each plate-shaped as described, for example, in EP 0 605 800 A1. The resistance element is preferably thinner than the adjacent connectors here, whereby the resistance element is preferably set back in relationship to the printed circuit board. This is a good idea to prevent the solder flowing onto the resistance element during the soldering process but contacting the respective connector exclusively. If the solder were to flow onto the resistance element, a parallel connection would occur on the outer side edges of the resistance element via the solder, causing the geometrically determined resistance value of the resistance element to be falsified, thereby leading to a corresponding measurement error. The thinner resistance element therefore preferably closes flush with the adjacent connectors on the side facing away from the printed circuit board so that the resistance element on the side facing the printed circuit board is set back in relationship to the surface of the thicker connector. The solder therefore preferably has no direct contact with the resistance element, namely before, during and/or after the actual soldering process.

In a preferred embodiment of the invention the soldering temperature which reflects the desired temperature of the solder is closed-loop controlled. For this control, a desired setpoint value is determined for the soldering temperature, whereby the setpoint value depends on the composition of the respective solder. During the actual soldering process the actual value of the soldering temperature is constantly measured. Any deviation between the setpoint value of the soldering temperature and the measured actual value of the soldering temperature is determined. The electrical energization of the component is then set as dependent on the deviation between the setpoint and the actual value so that the actual value of the soldering temperature is adjusted to the setpoint value. In practice, the power of the electrical current flowing through the component is varied using this control mechanism.

Furthermore, in a preferred embodiment of the invention, the soldering temperature during the soldering process is varied in accordance with a stipulated temperature-time profile so that the temporal curve of the soldering temperature follows the stipulated temperature-time profile. The soldering temperature in accordance with the desired temperature-time profile can either be set as part of an open-loop control or closed-loop control.

The soldering temperature is preferably the temperature of the solder. However, it is frequently impossible to measure the temperature of the solder itself. In these cases it is alternatively possible in the invention to measure the temperature of the resistance element or of the connectors of the resistor in order to derive the temperature of the solder therefrom. The term of soldering temperature used in the invention is therefore to be understood generally and is not restricted to the temperature of the soldered connection itself.

The conducting material of the connectors of the resistor is preferably copper or a copper alloy so that the conducting material has a specific electrical resistance which is as low as possible. This is important so that the measurement of the electrical voltage drop across the resistance element is falsified as little as possible by the drop in voltage within the connectors.

By contrast, the resistance material of the resistance element can, for example, be a copper alloy such as a copper manganese alloy or a copper-manganese-nickel alloy (e.g. Cu84Ni4Mn12, i.e. Manganin®). However, in terms of the resistance material the invention is not restricted to the above materials mentioned by way of example.

However, in the preferred embodiment of the invention, the resistance material of the resistance element has a higher specific resistance than the conducting material.

It is furthermore to be mentioned that the connectors are preferably connected mechanically fixedly with the resistance element, in particular by a welded seam which can be manufactured for example by electron beam welding. It is advantageous here for the connection between the connectors and the resistance element to be heat-resistant and not to dissolve in the inventive soldering method.

It is furthermore to be mentioned that the resistance material of the resistance element is preferably low ohmic and therefore, for example, has a specific electrical resistance which is smaller than 2·10⁻⁴ Ω·m, 2·10⁻⁵ Ω·m or even smaller than 2·10⁻⁶ Ω·m.

By contrast, the conducting material of the connectors has a specific electrical resistance which is smaller than 10⁻⁵ Ω·m, 10⁻⁶ Ω·m or even smaller than 10⁻⁷ Ω·m.

It is furthermore to be mentioned that the connectors and the resistance element of the resistor in the invention are preferably plate-shaped, as described for example in EP 0 605 800 A1, whereby the plate-shaped connectors or the plate-shaped resistance element may preferably be planar or bent.

It is also to be mentioned that to melt the solder the component is energized with an electrical current which is sufficiently large to generate the heat necessary to melt the solder. The component is therefore energized during the soldering process preferably with a current of more than 200 A, 500 A, 1000 A or even more than 2000 A.

Finally, it is to be mentioned with respect to the inventive soldering method that the component to be assembled is preferably an SMD component which is mounted by surface mounting on the printed circuit board.

However, the invention comprises not only the above described soldering method but also a corresponding soldering device to solder the printed circuit board with the electrical component, whereby a heating device is provided in the form of a current source which energizes the component with the electrical current in order to melt the solder by the electrical heat loss arising in the component.

In addition, the inventive soldering device preferably has a temperature sensor in order to measure an actual value of the soldering temperature, whereby the soldering temperature reflects the temperature of the solder. The temperature sensor is preferably connected with a controller which triggers the current source as dependent on a deviation between a stipulated setpoint value of the soldering temperature and the measured actual value of the soldering temperature and adjusts the actual value of the soldering temperature to the stipulated setpoint value of the soldering temperature.

In addition, the inventive soldering device can have a control unit which provides a temperature-time profile for the soldering temperature, whereby the control unit triggers the controller or the current source in accordance with the temperature-time profile. The control unit can therefore set the setpoint value for the soldering temperature in accordance with the set temperature-time profile depending on the time or directly control the current source accordingly.

Finally, the invention also comprises a printed circuit board layout with a printed circuit board and an electrical component which is soldered with the printed circuit board by means of a solder. The inventive printed circuit board layout differs from conventional printed circuit board layouts in that the solder is melted by an electrical energization of the component which is reflected in the finished soldered connection and distinguishes the inventive printed circuit board layout from conventional printed circuit board layouts.

Other advantageous further developments of the invention are described in the dependent claims or explained in greater detail below together with the description of the preferred embodiments of the invention using the figures. The figures show as follows:

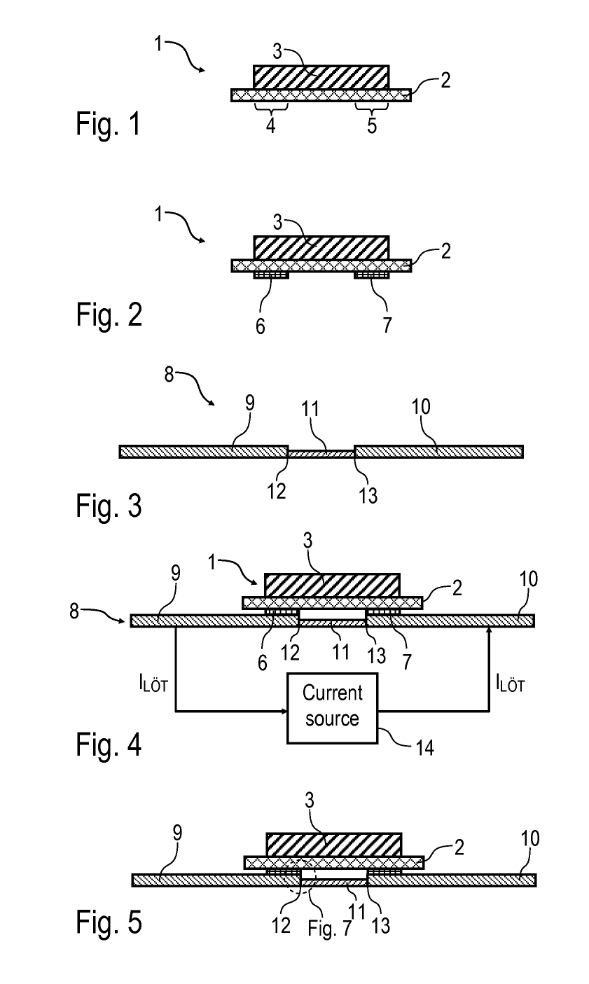

FIG. 1 a cross-sectional view through a printed circuit board with a measuring circuit mounted on top of it,

FIG. 2 a cross-sectional view of the printed circuit board layout from FIG. 1, whereby the underside of the soldering pads of the printed circuit board layout already have solering paste,

FIG. 3 a cross-sectional view through a current sense resistor,

FIG. 4 a cross-sectional view through an inventive soldering device to solder the printed circuit board layout in accordance with FIGS. 1 and 2 with the current sense resistor in accordance with FIG. 3,

FIG. 5 a cross-sectional view through the finished soldered printed circuit board layout,

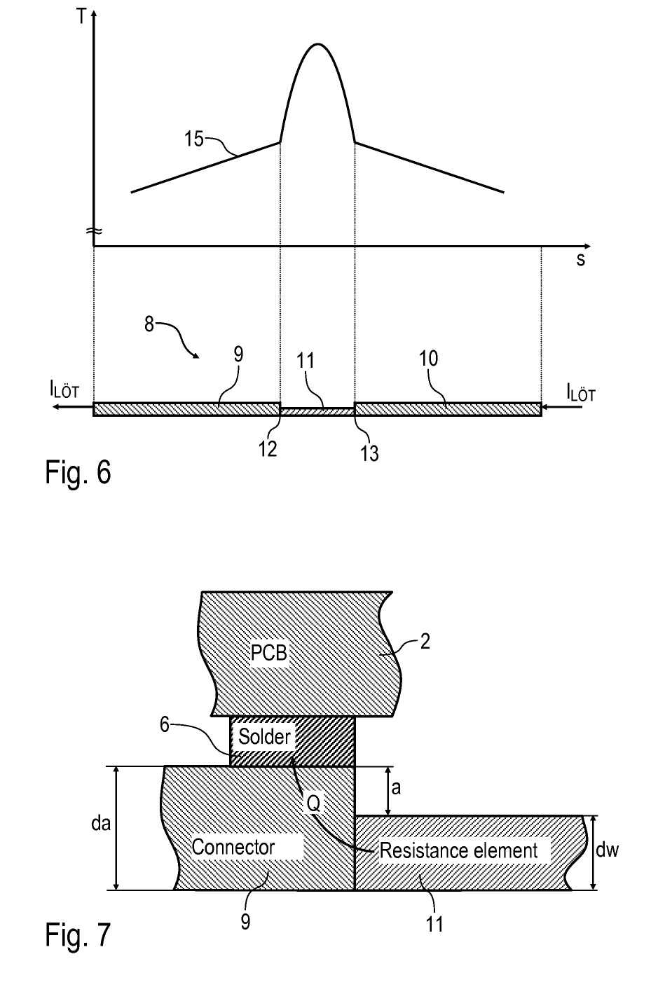

FIG. 6 a diagrammatic presentation of the temperature curve along the current sense resistor in accordance with FIG. 3 with an energization of the current sense resistor during the soldering process,

FIG. 7 an enlarged detailed view from FIG. 5 in the area of the soldered connection,

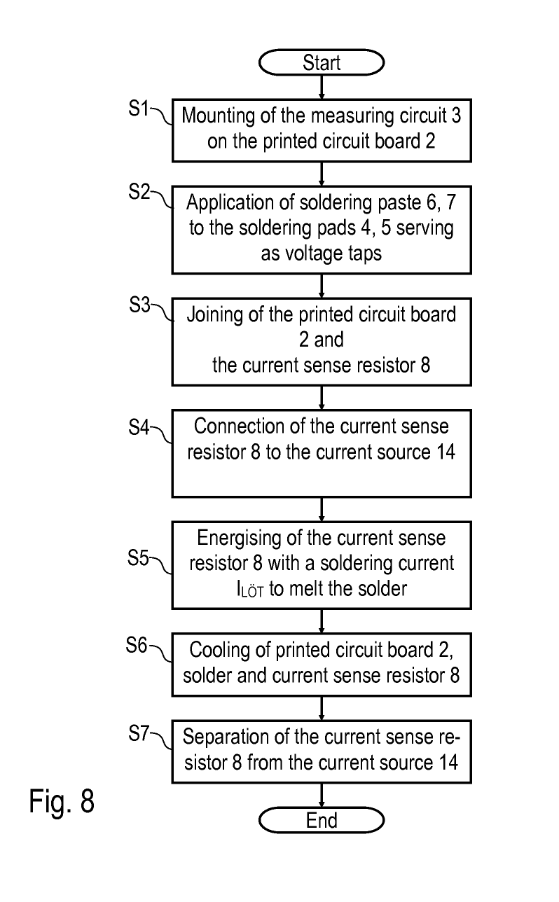

FIG. 8 the inventive soldering method in the form of a flow chart,

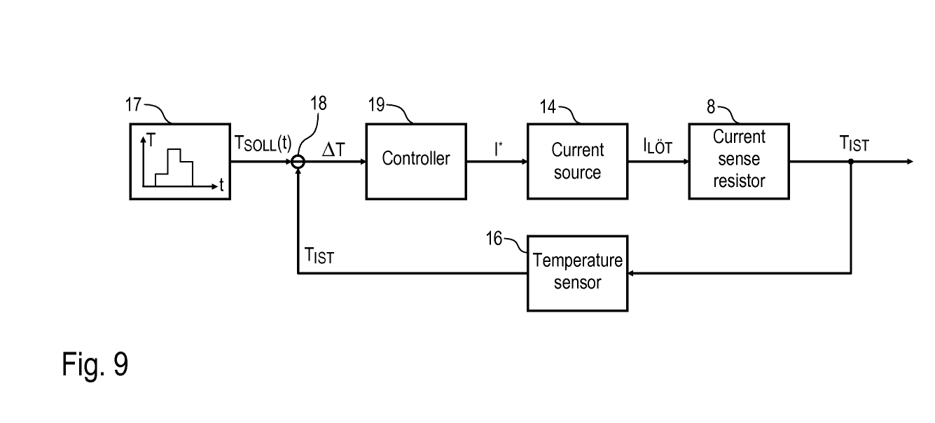

FIG. 9 a control circuit to control the soldering temperature in accordance with a preset temperature-time profile,

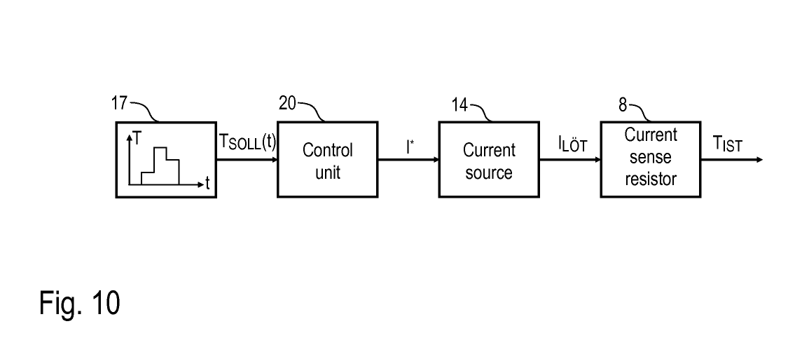

FIG. 10 a control unit to set the energization of the current sense resistor in accordance with a preset temperature-time profile, and

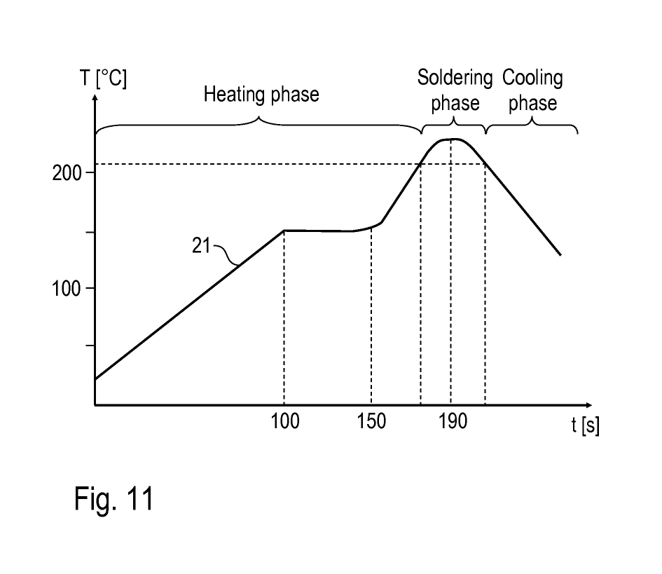

FIG. 11 a representation of a possible temperature-time profile of the energization by way of example.

FIG. 1 shows a simplified cross-sectional view of a printed circuit board layout 1 with a printed circuit board 2 and a measuring circuit 3 on top of it, whereby this can be, for example, an ASIC (Application Specific Integrated Circuit, as described, for example, in EP 1 363 131 A1. There are several soldering pads 4, 5 on the lower side of the printed circuit board 2 for electrical contacting, whereby the soldering pads 4, 5 are exposed contact areas.

FIG. 2 shows the printed circuit board layout 1 from FIG. 1 after application of the soldering paste 6, 7 to the soldering pads 4 and 5.

Furthermore, FIG. 3 shows a simplified cross-sectional view through a known current sense resistor 8 with two plate-shaped connectors 9, 10 made of copper or a copper alloy and a similarly plate-shaped resistance element 11 made of a resistance material such as Manganin®) (Cu84Ni4Mn12). The resistance element 11 is welded at its outer side edges 12, 13 with the connectors 9, 10, whereby the welding is preferably conducted by electron beam welding which is known from the state of the art. Furthermore it is to be mentioned here that the resistance element 11 is less thick than the adjacent connectors 9, 10 so that the resistance element 11 does not come into direct contact with the solder during the following soldering process, as is still to be described in detail.

FIG. 4 shows an inventive soldering device to solder the printed circuit board layout 1 from FIGS. 1 and 2 with the current sense resistor 8 from FIG. 3. For this purpose the printed circuit board layout 1 is joined with the current sense resistor 8 such that the soldering paste 6, 7 on the soldering pads 4, 5 of the printed circuit board 2 comes to rest on the connectors 9, 10 of the current sense resistor 8. It is also to be mentioned here that the soldering paste 6, 7 on the upper side of the connectors 9, 10 of the current sense resistor 8 reaches laterally up to the side edges 12, 13 of the resistance element 11 in order to create an electrical connection to the connectors 9, 10 directly at the side edges without creating a parallel connection to the resistance element 11.

In addition, the solder device comprises a current source 14 which is connected with the two connectors 9, 10 of the current sense resistor 8 and which energizes the current sense resistor 8 with a solder current I_{LÖT}, whereby the solder current I_{LÖT} may have a current strength of 1000 A, for example. The solder current I_{LÖT} firstly enters the connector 10 and then flows through the resistance element 11 and the connector 8 back to the current source 14. The solder current I_{LÖT} generates an electrical heat loss in the resistance element 11 which passes through the connectors 9, with a heat current Q to the soldering paste 6, 7 and causes it to melt, as is shown graphically in FIG. 7.

It can also be seen from the enlarged representation in FIG. 7 that the resistance element 11 has a thickness dw which is smaller than a thickness da of the connectors 9, 10, so that the upper side of the resistance element 11 is set back in relationship to the connectors 9, 10 by a distance a. The distance a is important here so that the solder 6 does not flow directly onto the resistance element during the solder process and comes into electrical contact with it because this would result in a parallel connection.

The diagrammatic representation in FIG. 6 furthermore shows a temperature curve 15 along the current sense resistor 8. It may be seen from this representation that the temperature T is highest in the middle of the resistance element 11 because the resulting heat loss must be dissipated laterally via the connectors 9, 10. By contrast, the greatest temperature inside the connectors 9, 10 is at the side edges 12, 13 of the resistance element 11. This is advantageous because the connecting elements 9, 10 are to be electrically contacted here so that the measurement of the voltage which drops across the resistance element 11 is not falsified by voltage drops within the connectors 9, 10.

FIG. 8 shows the inventive soldering method in the form of a flow chart.

In a first step S1, the measuring circuit 3 is mounted on the printed circuit board 2.

In a further step S2, the soldering paste 6, 7 is attached to the soldering pads 4, 5 of the printed circuit board 2.

In a step S3, the printed circuit board layout 1 is then joined with the current sense resistor 8.

The current sense resistor 8 is then connected in a step S4 to the current source 14 so that the current sense resistor 8 can then be energized with the soldering current I_{LÖT} in a step S5 in order to melt the soldering paste 6, 7.

Finally, the printed circuit board 1 with the soldering paste 6, 7 and the current sense resistor 8 is then cooled in a step S6, so that the melted soldering paste 6, 7 becomes rigid and creates an electrical and mechanical connection between the soldering pads 4, 5 and the connectors 9, 10 of the current sense resistor 8.

In a step S7, the current sense resistor 8 is then isolated from the current source 14.

FIG. 9 shows a simplified representation of a control circuit to control the energization of the current sense resistor 8 by the current source 14 in the inventive soldering method.

The inventive soldering device comprises a temperature sensor 16 which measures an actual value T_{IST} of the soldering temperature. For example, the temperature sensor 16 can directly measure the temperature of the soldering paste 6, 7. However, the temperature sensor 16 usually measures the temperature of the connectors 9, 10 in the area of the side edges 12, 13, which is considerably easier from a technical point of view.

In addition, the inventive soldering device with the control circuit shown comprises a control unit 17 which provides a temperature-time profile for a desired setpoint value T_{SOLL} of the soldering temperature.

The measured actual value T_{IST} of the soldering temperature is then entered into a subtracter 18 together with the time-dependent setpoint value T_{SOLL} which calculates a setpoint to actual value deviation ΔT and inputs this to a controller 19.

Depending of the deviation ΔT between setpoint and actual value, the controller 19 generates an adjustment variable I* for the current source 14 so that the current source 14 adjusts the soldering current I_{LÖT} accordingly, whereby the actual value T_{IST} of the soldering temperature is controlled to the stipulated setpoint value T_{SOLL} for the soldering temperature.

FIG. 10 shows an alternative embodiment of an inventive soldering device, whereby this embodiment corresponds partly to the embodiment described above and shown in FIG. 9 so that reference is made to the above description to avoid repetition, whereby the same reference figures are used for the corresponding details.

A special feature of this embodiment is that an open-loop controller 20 is provided instead of the closed-loop controller 19, whereby the open-loop controller 20 controls the current source 14 without a feedback in accordance with the set temperature-time profile.

Finally, FIG. 11 shows a simplified representation of a possible temperature-time profile 21 with a heating phase, a soldering phase and a cooling phase, whereby the temperature-time profile 21 is known from the state of the art and need not therefore be described in any further detail.

The invention is not restricted to the above-described preferred embodiments. Rather, a large number of versions and modifications are possible which similarly make use of the inventive concept and which therefore fall within the protective area. In addition, the invention also claims protection for the subject matter and features of the dependent claims irrespective of the features of the claims referred to.

### REFERENCE NUMBER LIST

1 Printed circuit board layout
2 Printed circuit board
3 Measuring circuit
4 Soldering pad
5 Soldering pad
6 Soldering paste
7 Soldering paste
8 Current sense resistor
9 Connector
10 Connector
11 Resistance element
12 Side edge of the resistance element
13 Side edge of the resistance element
14 Current source
15 Temperature curve
16 Temperature sensor
17 Control unit
18 Subtractor
19 Controller
20 Open-loop controller
21 Temperature-time profile
ΔT Deviation between setpoint and actual value
T_{LÖT} Soldering temperature
dw Thickness of the resistance element
da Thickness of the connector
a Distance
I_{LÖT} Soldering current
I* Adjustment variable for current source
Q Heat current from resistance element to the soldering point
T_{IST} Actual value of the soldering temperature
T_{SOLL} Setpoint value of the soldering temperature

1. Soldering method to solder a printed circuit board to an electric component using a solder, said method comprising electrically energizing the electrical component to generate heat to melt the solder such that the solder connects the electrical component to the printed circuit board, wherein the electrically energizing generates an electrical heat loss in the electric component, which passes from the electric component and causes the solder and causes the solder to melt.

2. Soldering method in accordance with claim 1, wherein
a) the electrical component is a passive component, and
b) the electrical component is a resistor which comprises a resistance element made of a resistance material and two connectors made from a conducting material, whereby the resistance element is connected electrically between the two connectors, and
c) the electrical heat loss arising from the energizing passes from the resistance element via the connectors of the resistor to the solder and causes the solder to melt.

3. Soldering method in accordance with claim 2, further comprising the following steps:
a) Applying the solder to soldering pads of the printed circuit board and to the connectors of the resistor,
b) Assembly of the printed circuit board with the resistor, so that the solder is located between the soldering pads of the printed circuit board and the connectors of the resistor,
c) Energizing the resistor with an electrical current, so that the electrical heat loss arising in the resistance element passes through the connectors of the resistor to the solder and causes the solder to melt, and
d) Cooling of the resistor and the printed circuit board together with the solder after energizing ends, so that the solder becomes rigid and connects the connectors of the resistor electrically to the soldering pads of the printed circuit board.

4. Soldering method in accordance with claim 3, wherein
the soldering pads of the printed circuit board form voltage taps in order to measure a drop in voltage across the resistance element of the resistor.

5. Soldering method in accordance with claim 2, further comprising the following steps:
a) Mounting of an electronic measurement circuit on the printed circuit board to measure a drop in voltage across the resistance element of the resistor,
b) Creation of an electrical connection between the connectors of the resistor and the measurement circuit.

6. Soldering method in accordance with claim 2, wherein
a) the two connectors and the resistance element are both plate-shaped, and
b) the resistance element has a thickness which is smaller than the thickness of the two adjacent connectors, and
c) the resistance element on a side facing the printed circuit board is set back in relationship to an area of the adjacent connectors facing the printed circuit board in order to avoid a direct heat contact between the resistance element and the solder, and
d) the resistance element on a side facing away from the printed circuit board is flush with the adjacent connectors, and
e) the solder has no direct contact with the resistance element before, during and/or after the soldering process.

7. Soldering method in accordance with claim 1, further comprising: a closed-loop control with the following steps:
a) Predetermination of a setpoint value for a soldering temperature, whereby the setpoint value reflects a desired temperature of the solder,
b) Measurement of an actual value of the soldering temperature,
c) Determination of a deviation between the setpoint value and the actual value of the soldering temperature,
d) Adjustment of the electrical energization of the component depending on the deviation between the setpoint value and the actual value, so that the actual value of the soldering temperature is controlled to the setpoint value.

8. Soldering method in accordance with claim 1, further comprising the following steps:
a) Predetermination of a temperature-time profile for a desired time curve of a soldering temperature, and
b) Open-loop controlling or closed-loop controlling the soldering temperature in accordance with the desired temperature-time profile by varying the energization of the component in accordance with the predetermined temperature-time profile.

9. Soldering method in accordance with claim 7, wherein the soldering temperature is one of the following parameters:
a) the temperature of the resistance element,
b) the temperature of the solder,
c) the temperature of the connectors.

10. Soldering method in accordance with claim 2, wherein
a) the conducting material of the connectors is copper or a copper alloy, and
b) the resistance material of the resistance element is a copper alloy, and
c) the resistance material of the resistance element has a higher specific resistance than the conductor material of the connectors, and
d) the connectors are connected with the resistance element in a mechanically fixed manner, and
e) the resistance material is low ohmic, and
f) the resistance material has a specific electrical resistance which is smaller than 2·10⁻⁴ Ω·m, and
g) the conducting material has a specific electrical resistance which is smaller than 10⁻⁵ Ω·m, and
h) the connectors and/or the resistance element are plate-shaped, and
i) the connectors are planar or bent, and
j) the component is energized to melt the solder with an electrical current of more than 200 A, and
k) the component is an SMD component.

11. Soldering device to solder a printed circuit board to an electrical component said soldering device comprising a heating device to heat the solder, wherein the heating device is a current source which energizes the electrical component with an electrical current, whereby the electrical current generates a heat loss in the electrical component, which passes from the electrical component to the solder and causes the solder to melt.

12. Soldering device in accordance with claim 11, further comprising
a) a temperature sensor to measure an actual value of a soldering temperature, whereby the soldering temperature reflects the soldering temperature of the solder, and
b) a controller which controls the current source depending on a deviation between a stipulated setpoint value of the soldering temperature and a measured actual value of the soldering temperature and controls the actual value of the soldering temperature to the stipulated setpoint value of the soldering temperature.

13. Soldering device in accordance with claim 12, further comprising a control unit to set a temperature-time profile for a soldering temperature which reflects a temperature of the solder whilst the temperature-time profile defines a desired temporal curve of the soldering temperature, whereby the control unit controls the controller or the current source in accordance with the temperature-time profile.

14. Printed circuit board layout with a printed circuit board and an electrical component which is soldered to the printed circuit board by a solder, wherein the solder was melted by an electrical energization of the component.

15. Soldering method according to claim 4, wherein the soldering pads serving as voltage taps of the printed circuit board contact with the connectors of the resistor directly at a transition between the connectors and the resistance element.
